(19) United States
(12) Patent Application Publication
(10) Pub. No.: US 2005/0058170 A1
(43) Pub. Date: Mar. 17, 2005

(54) Semiconductor laser element and semiconductor laser element manufacturing method

(75) Inventors: Yoshiyuki Itoh, Saitama-shi (JP); Toshiyuki Terada, Kawasaki-shi (JP); Shunji Yoshitake, Kawasaki-shi (JP)

Correspondence Address: BANNER & WITCOFF, LTD., ATTORNEYS FOR RESERVE;CLIENT NO. 4, 1001 G STREET, N.W., 11TH FLOOR, WASHINGTON, DC, 20001-4597, US

(73) Assignee: Kabushiki Kaisha Toshiba, Minato-ku (JP)

(21) Appl. No.: 10/938,660

(22) Filed: Sep. 13, 2004

(30) Foreign Application Priority Data
Sep. 17, 2003 (JP) 2003-325085

(51) Int. Cl. H01S 5/00

(52) U.S. Cl. 372/44; 372/49

(57) ABSTRACT

Disclosed is a semiconductor laser element including: a double heterojunction structure having a p-type clad layer; a second p-type clad layer formed on the double heterojunction structure, having a first dopant and a ridge shape; a p-type contact layer formed on the second p-type clad layer, having a second dopant whose diffusion velocity is slower than that of the first dopant; a dielectric film covering a side surface of the second p-type clad layer and the p-type contact layer, and a surface on which the second p-type clad layer is not formed on the double heterojunction structure; and a p-side electrode formed on the p-type contact layer. Meanwhile, disclosed is a semiconductor laser element including a similar double heterojunction structure, a second p-type clad layer, a p-type contact layer, and a p-side electrode, with end faces of cleavages of the double heterojunction structure thereof being an unmarshalled layer structure.

### CROSS-REFERENCE TO THE RELATED APPLICATIONS

This application is based upon and claims the benefit of priority from the prior Japanese Patent Application No. 2003-325085, filed on Sep. 17th, 2003; the entire contents of which are incorporated herein by reference.

### BACKGROUND

1. FIELD OF THE INVENTION

The present invention relates to a semiconductor laser element which emits a laser light from an end face of a cleavage as well as a manufacturing method thereof, more particularly to a semiconductor laser element which has a ridge waveguide structure and provide a high optical output power as well as a manufacturing method thereof.

2. DESCRIPTION OF THE RELATED ART

Recently, a red semiconductor laser with an emitted light wavelength of 650 nm band by an InGaAlP material system is in practical use, and an optical disc system of DVD (digital versatile disc) standard using this laser is beginning to spread rapidly. At the outset a DVD-ROM (read only memory) drive which only reads information being a mainstream, recently an image recording device to replace a VTR (video tape recorder) and a high capacity data storage device to replace a CD-R (compact disc-recordable) are becoming popular. Such DVDs for writing require a red semiconductor laser of a higher output power. Moreover, in order for high-speed writing, an additional increase in the output power is indispensable, and at present a special emphasis is put on a development of the semiconductor laser having the output power of, for example, 200 mW and above.

For the semiconductor laser of the above wavelength, one having a double heterojunction structure which is constituted with the InGaAlP material system on a GaAs base is usually used. Further, by converting an upper clad layer of the double heterojunction structure into a ridge shape and forming on both sides thereof a current stopping layer of a material which does not absorb (reflects) an emitted light, a so-called real refractive index waveguide structure is obtained, and this is often used.

These structures in themselves are disclosed, though there exist differences in the emitted light wavelength and the material system, in Japanese Patent Laid-open Application No. Hei 10-135567, for example. In disclosure by this document, for a current stopping layer a semiconductor material with a different conductive type from that of a neighboring clad layer thereof is used.

[Patent document 1] Japanese Patent Laid-open Application No. Hei 10-135567

A semiconductor laser compliant to a high optical output power virtually requires a structure for preventing so-called end face destruction, but the above document does not refer to this point.

### SUMMARY

A semiconductor laser element according to one aspect of the present invention includes: a double heterojunction structure having an n-type clad layer, an active layer formed on the n-type clad layer, and a p-type clad layer formed on the active layer; a second p-type clad layer formed on the double heterojunction structure, containing a first dopant, and having a ridge shape; a p-type contact layer formed on the second p-type clad layer and having a second dopant of which a diffusion velocity is slower than that of the first dopant; a dielectric film covering a side surface of the second p-type clad layer, a side surface of the p-type contact layer, and a surface on which the second p-type clad layer is not formed on the double heterojunction structure; and a p-side electrode formed on the p-type contact layer.

Additionally, a semiconductor laser element according to another aspect of the present invention includes: a double heterojunction structure having an n-type clad layer, an active layer formed on the n-type clad layer, and a p-type clad layer formed on the active layer; a second p-type clad layer formed on the double heterojunction structure, containing a first dopant, and having a ridge shape; a p-type contact layer formed on the second p-type clad layer and having a second dopant of which a diffusion velocity is slower than that of the first dopant; and a p-side electrode formed on the p-type contact layer. Further, an end face of a cleavage of the double heterojunction structure thereof is an unmarshalled layer structure.

Additionally, a manufacturing method of the semiconductor laser element according to one aspect of the present invention includes: forming a double heterojunction structure which has an n-type clad layer, an active layer positioned on the n-type clad layer, and a p-type clad layer positioned on the active layer; forming a second p-type clad layer on the formed double heterojunction structure; forming a p-type contact layer which contains carbon as a dopant on the formed second p-type clad layer; converting the second p-type clad layer and the p-type contact layer into a ridge shape; depositing a dielectric film on a side surface of the second p-type clad layer and the p-type contact layer converted into the ridge shape as well as on a surface on which the second p-type clad layer is not formed on the double heterojunction structure; and forming a p-side electrode to contact a top surface of the p-type contact layer.

### BRIEF DESCRIPTION OF THE DRAWINGS

FIG. 1 is a perspective view which schematically shows a structure of a semiconductor laser device according to an embodiment of the present invention.

FIG. 2A and FIG. 2B are schematic perspective views which show a process of manufacturing the semiconductor laser device according to an embodiment of the present invention.

FIG. 3A and FIG. 3B to continue from FIG. 2B are schematic perspective views which show the process of manufacturing the semiconductor laser device according to an embodiment of the present invention.

FIG. 4A and FIG. 4B to continue from FIG. 3B are schematic perspective views which show the process of manufacturing the semiconductor laser device according to an embodiment of the present invention.

FIG. 5 to continue from FIG. 4B is a schematic perspective view which shows the process of manufacturing the semiconductor laser device according to an embodiment of the present invention.

FIG. 6 is a perspective view which schematically shows a structure of a semiconductor laser device according to another embodiment of the present invention.

FIG. 7 is a perspective view which schematically shows a structure before formation of a p-side electrode 23 and an n-side electrode 22 in the structure shown in FIG. 6.

FIG. 8 is a perspective view which schematically shows a structure of a semiconductor laser element as a comparative example.

FIG. 9 is a perspective view which schematically shows a structure of a semiconductor laser element as another comparative example.

### DETAILED DESCRIPTION

(Description of Embodiments)

Embodiments of the present invention will be described with reference to the drawings, but these drawings are presented only for the illustrative purpose and in no respect, are intended to limit the present invention.

In a semiconductor laser element according to one aspect of the present invention, for a current stopping layer formed on side surfaces of a second p-type clad layer as well as surfaces on which the second p-type clad layer is not formed on a double heterojunction structure, a dielectric film with stable temperature characteristics is used. According thereto an increase in a leak current is prevented. Additionally, in a p-type contact layer formed on the second p-type clad layer, for a dopant which is required to be highly concentrated, a material with a slower diffusion velocity than a dopant for the second p-type clad layer is used. According thereto dopant diffusion from the p-type contact layer to, for example, the active layer is suppressed even under high temperature processing at a time of forming the dielectric film as the current stopping layer. Therefore, deterioration of both the active layer and the p-type contact layer can be prevented. Consequently, it is possible to eliminate a characteristic deterioration factor, so that a high output semiconductor laser can be obtained.

In a production method of the semiconductor laser element according to one aspect of the present invention, the steps of producing the above-described semiconductor laser are provided. Consequently, it is possible to produce the high output semiconductor laser in which the characteristic deterioration factor is eliminable.

In a semiconductor laser element according to another aspect of the present invention, in a p-type contact layer formed on a second p-type clad layer, for a dopant which is required to be highly concentrated a material with a slower diffusion velocity than a dopant for the second p-type clad layer is used. This suppresses dopant diffusion from the p-type contact layer to, for example, the active layer even under high temperature processing at a time of forming a dielectric film as the current stopping layer. Therefore, deterioration of both the active layer and the p-type contact layer can be prevented. Further, since end faces of cleavages of a double heterojunction structure are unmarshalled layer structures, damage at a time of a high output power is reduced. Consequently, it is possible to eliminate a characteristic deterioration factor, so that a high output semiconductor laser is obtainable.

As a mode of the present invention, the first dopant/the second dopant can be zinc/carbon, zinc/magnesium, or magnesium/carbon. These are examples of combination of the first dopant and the second dopant with a slower diffusion velocity than the first dopant.

Additionally, as mode of the present invention (the one aspect above), end faces of cleavages of the double heterojunction structure can have an unmarshalled layer structure (so-called window structure). According thereto, light absorption in neighborhood of the end faces of the cleavages is suppressed and occurrence of so-called end face destruction (catastrophic optical damage: COD) can be effectively suppressed. These structures can be formed, as a mode of a production method, by having an additional step of unmarshalling a layer structure in some areas of the double heterojunction structure, after the forming the second p-type clad layer and before the forming the p-type contact layer.

As another mode of the present invention, the active layer can be a single quantum well structure or a multiple quantum well structure. According to this structure, when end faces of cleavages of a double heterojunction structure have an unmarshalled layer structure, an avoidance effect of optical damage is high.

As still another mode of the present invention (the one aspect above), the dielectric film is a film essentially composed of silicon oxide. This is an example of the easiest use for the dielectric film. Other films composed of such as silicon nitride or zirconium oxide can be adopted.

As yet another mode of the present invention, the n-type clad layer, the p-type clad layer, and the second p-type contact layer have an InGaAlP composition, while the active layer has an InGaP composition. This is a preferable example of a material system to work the present invention.

As yet another mode, the p-type contact layer has a GaAs composition and a carrier concentration of the p-type contact layer is 1×10¹⁹cm⁻³ to 5×10¹⁹cm⁻³. According to such a p-type contact layer, an ohmic connection to the p-side electrode is relatively easy, contributing to an operation at a low threshold voltage or a highly efficient light emission.

As yet another mode, a wavelength of an emitted laser light is almost 650 nm. According thereto, use in a writable DVD is possible.

As yet another mode of the present invention (the one aspect above), the dielectric film can cover parts of upper surface in neighborhood of end faces of the p-type contact layer. According thereto, a current prevention effect is exerted also to the endfaces, so that, for example when the window structure is formed, a current which does not contribute to a light emission is suppressed and a Joule heat thereof is also suppressed. Consequently, this can contribute to a more highly efficient light emission.

As yet another mode, an emitted laser light output power is 200 mW and above. Practically securing this output power achieves, for example in a writable DVD system, higher speed writing (for example, 16×).

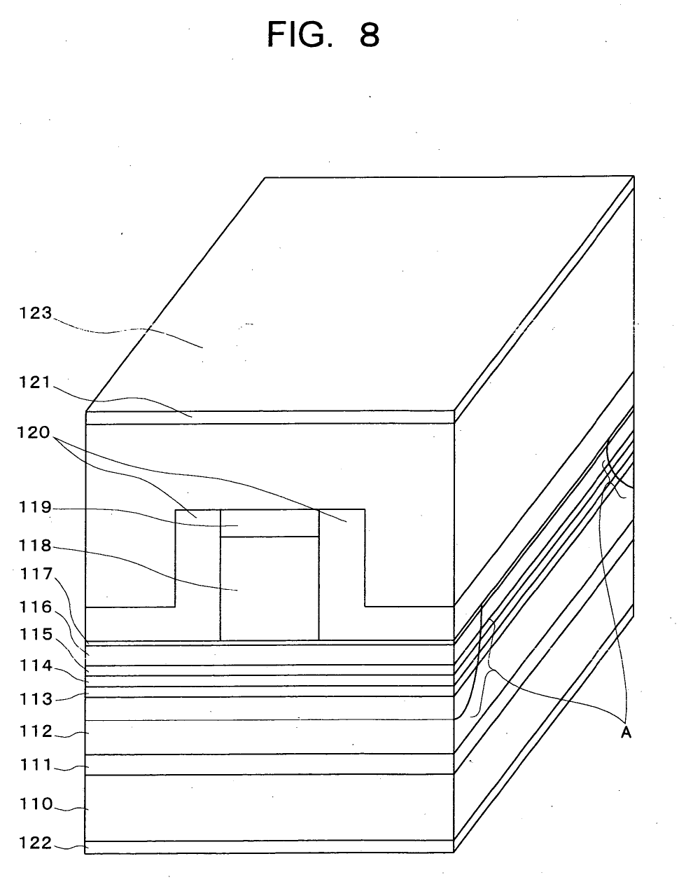

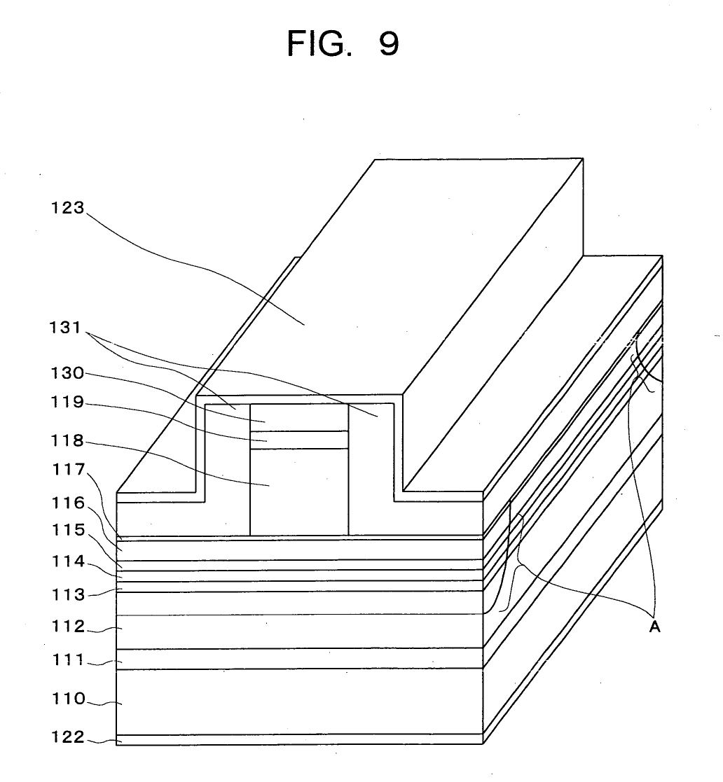

Based on the above, embodiments of the present invention will be hereinafter described with reference to the drawings. First, two comparative examples are described (FIG. 8 and FIG. 9).

FIG. 8 is a perspective view which schematically shows a structure of a semiconductor laser element (more particularly, ridge waveguide semiconductor laser element) for comparison. To describe the structure of this semiconductor laser element along a manufacturing process, first, by using for example a MOCVD (Metal Organic Chemical Vapor Deposition) method, sequentially grown on an n-GaAs substrate 110 are: an n-GaAs buffer layer 111, an n-In_{0.5}(Ga_{0.3}Al_{0.7})_{0.5}P clad layer 112, an In_{0.5}(Ga_{0.5}Al_{0.5})_{0.5} P light guide layer 113, an InGaP/InGaAlP-MQW (Multiple Quantum Well) active layer 114, an In_{0.5}(Ga_{0.5}Al_{0.5})_{0.5}P light guide layer 115, a p-In_{0.5}(Ga_{0.3}Al_{0.7})_{0.5}P clad layer 116, a p-In_{0.5}Ga_{0.5}P etching stop layer 117, a p-In_{0.5}(Ga_{0.3}Al_{0.7})_{0.5}P clad layer 118, and a p-In_{0.5}Ga_{0.5}P intermediate layer 119.

Next, on a part A (both front and back end faces in FIG. 8), which corresponds to end faces of cleavages of the semiconductor laser element, zinc is diffused to unmarshal a layer structure and form a so-called window structure. Subsequently, by a PEP (Photo Engraving Process), stripe shape (stripes in longitudinal direction in FIG. 8) patterning of a photoresist (coated on a top surface) is conducted, and then with a mask thereof, wet etching, dry etching, or a combined method of both and the like is used to form a stripe ridge shape to the p-In_{0.5}(Ga0_{0.3}Al_{0.7})_{0.5}P clad layer 118.

Next, on both sides of this formed ridge as well as on exposed surfaces of the p-In_{0.5}Ga_{0.5}P etching stop layer 117, an n-In_{0.5}Al_{0.5}P current stopping layer 120 is crystal grown. Subsequently, on the entire formed layers of the above, a p-GaAs contact layer 121 doped with zinc is grown. Additionally formed are a p-side electrode 123 on the grown p-GaAs contact layer 121 and an n-side electrode 122 on an undersurface of the n-GaAs substrate 110, respectively. According to the above, the structure shown in FIG. 8 is obtained.

In this semiconductor laser element, the material of the current stopping layer 120, which is n-In_{0.5}Al_{0.5}P, deposits on the mask necessary for forming the current stopping layer 120 except on the p-In_{0.5}Ga_{0.5}P intermediate layer 119, to cause a disadvantage that removal of this deposit and the mask is difficult. In addition, a residue and the like generated in the above process degrades crystallinity of the p-GaAs contact layer 121 in neighborhood of a stripe ridge portion, and it is possible that a light emission of the semiconductor laser element is deteriorated.

FIG. 9 is a perspective view which schematically shows another structure of a semiconductor laser element (ridge waveguide semiconductor laser element) for comparison. This semiconductor laser element differs from the comparative example described above in that this semiconductor laser element uses a dielectric film for a current stopping layer. Note that in FIG. 9 the same reference numerals and symbols are used to designate the same portions as those shown in FIG. 8 and explanation thereof will be restrained except when necessary.

To describe the structure of this semiconductor laser element along a manufacturing process, first by using for example a MOCVD method, from an n-GaAs buffer layer 111 to a p-In_{0.5}Ga_{0.5}P intermediate layer 119 are sequentially grown on an n-GaAs substrate 110. Then, on a part A (both front and back end faces in FIG. 9), which corresponds to end faces of cleavages of the semiconductor laser element, zinc is diffused to unmarshal a layer structure and form a so-called window structure. Subsequently, on an entire top surface of the intermediate layer 119, a p-GaAs contact layer 130 doped with zinc in high concentration is formed.

Next, by a PEP, stripe shape (stripes in longitudinal direction in FIG. 9) patterning of a photoresist (coated on a top surface) is conducted, and then with a mask thereof, wet etching, dry etching, or a combined method of both and the like is used to form a stripe ridge shape to a p-In_{0.5}(Ga_{0.3}Al_{0.7})_{0.5}P clad layer 118. Then, on both sides of this formed ridge as well as on exposed surfaces of a p-In_{0.5}Ga_{0.5}P etching stop layer 117, a current stopping layer 131 of a dielectric (silicon oxide) is formed. Additionally, a p-side electrode 123 is formed, so as to contact a top surface of the contact layer 130, on the entire formed layers above, and an n-side electrode 122 is formed on an undersurface of an n-GaAs substrate 110, respectively. According to the above, the structure shown in FIG. 9 is obtained.

In this semiconductor laser element, since the dielectric current stopping layer 131 is formed after formation of the p-GaAs contact layer 130 which is doped with zinc in higher concentration, there is a possibility that a thermal history makes this zinc diffuse toward the active layer 114 and that a light emission of the semiconductor laser element is deteriorated. Further, a lack of carrier concentration of the p-GaAs contact layer 130 caused by diffusion of zinc can make non-alloy type ohmic electrode formation at the p-side electrode 123 difficult. Therefore, though the semiconductor laser element described above is better suited for realizing a high output power than the example shown in FIG. 8, limitation exists for realizing a high output power because of some characteristic deterioration factors.

Incidentally, in the example shown in FIG. 9, such a manufacturing process is conceivable as to crystal grow the p-GaAs contact layer 130 after deposit of the dielectric current stopping layer 131 in order to avoid zinc diffusion. However, an area for epitaxial growth thereof is limited to an area of a minimal width on the ridge shape, and control of impurity concentration or film thickness is quite difficult, therefore such a manufacturing process can not be said to be realistic.

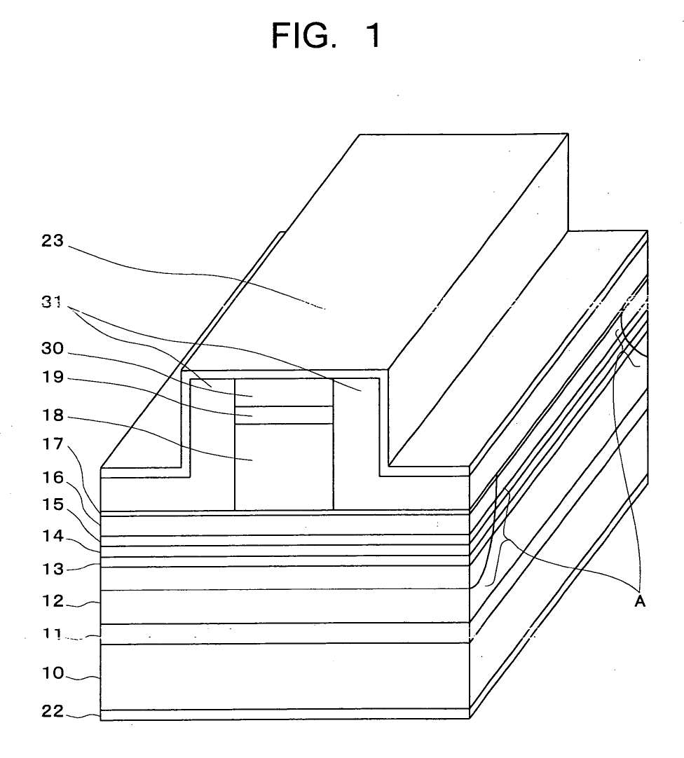

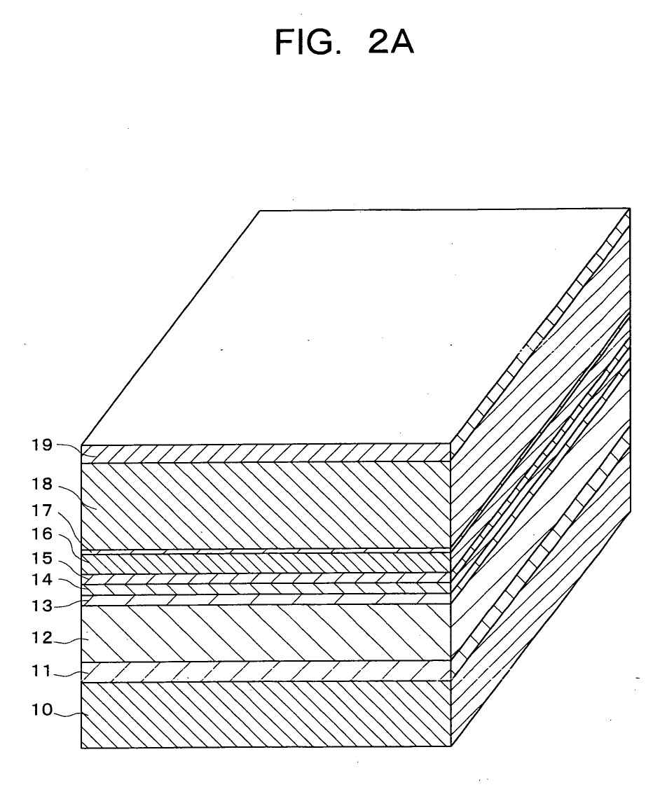

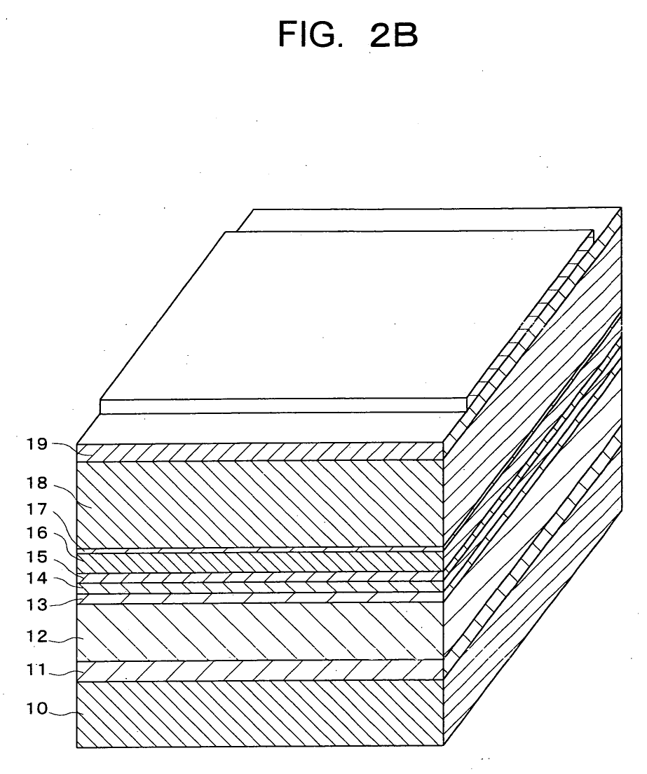

Next, a semiconductor laser device according to an embodiment of the present invention will be described with reference to FIG. 1 to FIG. 5. FIG. 1 is a perspective view which schematically shows a structure of the semiconductor device according to an embodiment of the present invention. FIG. 2A to FIG. 5 are perspective views which schematically show a process to manufacture the semiconductor laser device according to an embodiment of the present invention.

As shown in FIG. 1, this semiconductor laser device is a same type of ridge waveguide semiconductor laser element as one shown in FIG. 9 which uses a dielectric film for a current stopping layer, and its basic layer structure in itself is the same except some compositions as the structure in FIG. 9. More specifically, built respectively on each entire surface on a n-GaAs substrate 10 are: an n-GaAs buffer layer 11, an n-In_{0.5}(Ga_{0.3}Al_{0.7})_{0.5}P clad layer 12 with a carrier concentration of 3×10¹⁷cm⁻³ for example, an In_{0.5}(Ga_{0.5}Al_{0.5})_{0.5}P light guide layer 13, an InGaP/InGaAlP-MQW active layer 14, an In_{0.5}(Ga_{0.5}Al_{0.5})_{0.5}P light guide layer 15, a p-In_{0.5}(Ga_{0.3}Al_{0.7})_{0.5}P clad layer 16 with a carrier concentration of 1×10¹⁸cm⁻³ for example, and a p-In_{0.5}Ga_{0.5}P etching stop layer 17 with a carrier concentration of 1×10¹⁸cm⁻³ for example.

Additionally, formed on the etching stop layer 17 are: a stripe etched p-In_{0.5}(Ga_{0.3}Al_{0.7})_{0.5}P clad layer 18 (a dopant thereof is zinc) with a carrier concentration of 1×10¹⁸cm⁻³ for example, a p-In_{0.5}Ga_{0.5}P intermediate layer 19 with a carrier concentration of 1×10¹⁸cm⁻³ for example, and a p-GaAs contact layer 30. For the contact layer 30, carbon is used as a dopant, of which a carrier concentration is 3×10¹⁹cm⁻³ for example.

Further, so as to cover side surfaces of each of layers processed in stripes as well as exposed surfaces of the p-In_{0.5}Ga_{0.5}P etching stop layer 17, a current stopping layer 31 of a dielectric (here, silicon oxide: SiO₂) is formed. Moreover, so as to contact a top surface of the contact layer 30, on the entire formed layers described above, a p-side electrode 30 is formed, while on an undersurface of the GaAs substrate 10 an n-side electrode 22 is formed. Here, by using a stacked film containing a titanium based metal thin film, for example, for the p-side electrode 23, an ohmic connection to the P-GaAs contact layer 30 can be obtained.

Incidentally, the InGaP/InGaAlP-MQW active layer 14 has, for example, two or three quantum well layers (each layer is for example 2-10 nm thick) of an InGaP composition, and so as to divide these quantum well layers, layers (each layer is for example 2-10 nm thick) of an InGaAlP composition are formed, therefore this is a stacked structure as a whole. Meanwhile, instead of the MQW active layer 14, use of an active layer of a single quantum well structure or a bulk active layer is also conceivable. In general, the MQW active layer or the active layer of the single quantum well structure can avoid an optical damage more effectively, when having a layer structure which is unmarshalled in neighborhood of end faces of cleavages. Size of the semiconductor laser element as a whole shown in FIG. 1 is for example 200-300 μm in width, for example 1000-1500 μm in depth, and for example 100-110 μm in height.

A manufacturing process of this semiconductor laser device will be described with reference to FIG. 2A to FIG. 5. In FIG. 2A to FIG. 5, the same reference numerals and symbols are used to designate the same elements as those shown in FIG. 1. Since this manufacturing is conducted as a semiconductor wafer manufacturing, in these drawings as individual semiconductor laser device manufacturing, hatching is added to parts represneting virtual cross sectional surfaces. In other words, this is actually a wafer manufacturing process.

First, as shown in FIG. 2A, on the n-GaAs substrate 10, from the n-GaAs buffer layer 11 to the p-In_{0.5}Ga_{0.5}P intermediate layer 19 are grown by, for example, a low pressure MOCVD method. Among these layers, those of which a carrier concentration is designated above are formed with the carrier concentration being set as described above. For a dopant for p-type or n-type, public known one can be used in view of combination with a material system. A thickness of each layer (or formation thickness) is, in view of a high optical output power compliance, for example, some hundred μm for the substrate 10, 0.5 μm for the buffer layer 11, 1.5-3 μm for the clad layer 12, 5-50 nm for the light guide layer 13, 6-50 nm for the active layer 14, 5-50 nm for the light guide layer 15, 0.2-0.5 μm for the clad layer 16, 5-30 nm for the etching stop layer 17, 1-3 μm for the clad layer 18, and 20-100 nm for the intermediate layer 19.

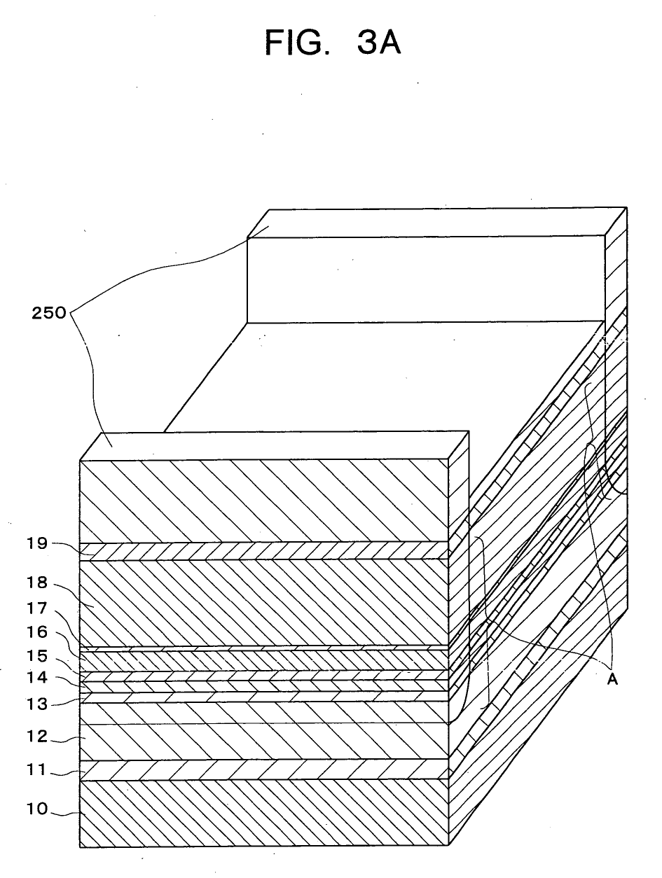

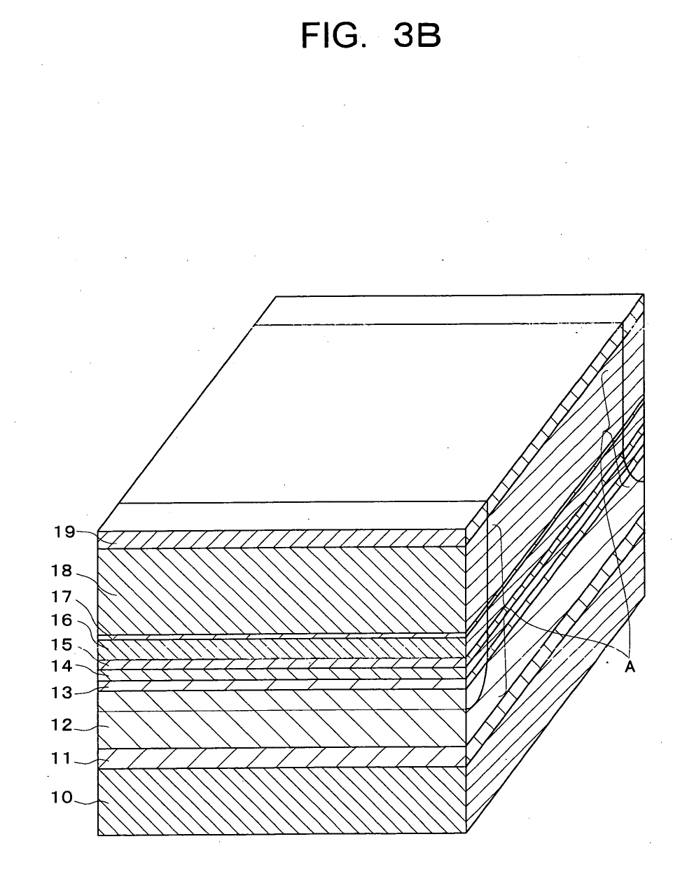

Next, using a public known photolithography technology and an etching technology, as shown in FIG. 2B, a pattern of SiO₂ is formed so as to cover the other part than openings left only in neighborhood of areas which become end faces of cleavages when a semiconductor laser element is made as one chip. Additionally, as shown in FIG. 3A, only on the openings of the above pattern, a zinc diffusion source (GaAs crystal added with zinc in high concentration) 250 is selectively grown. Then by heat treatment, zinc is diffused from the zinc diffusion source 250 in a vertical direction (“A” part), to form a so-called window structure. According to this window structure, a vicinity of the active layer 14 in neighborhood of end faces of cleavages become an unmarshalled layer structure, which can be prevented from being an absorption area of generated laser light. Consequently, a structure in which end face destruction is hard to occur can be obtained.

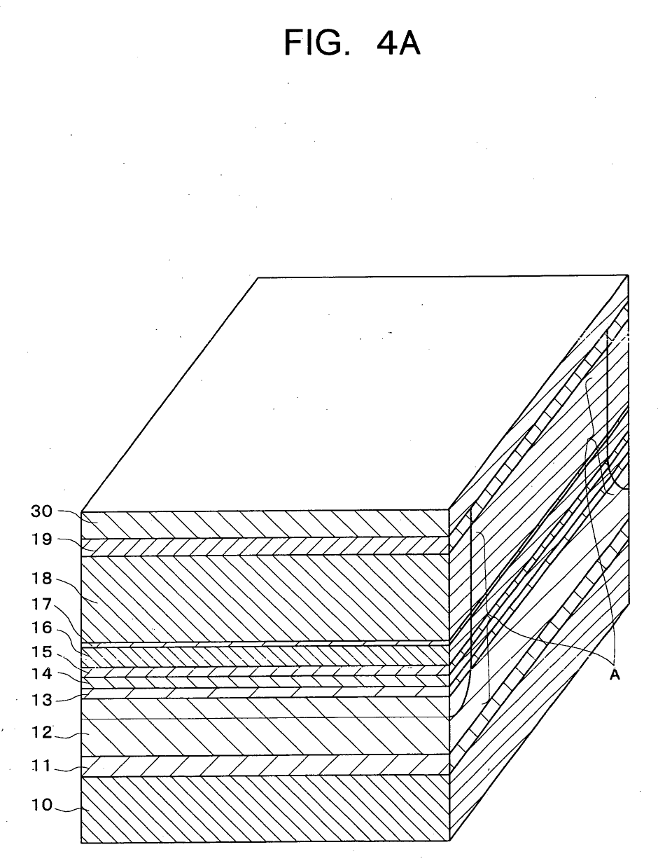

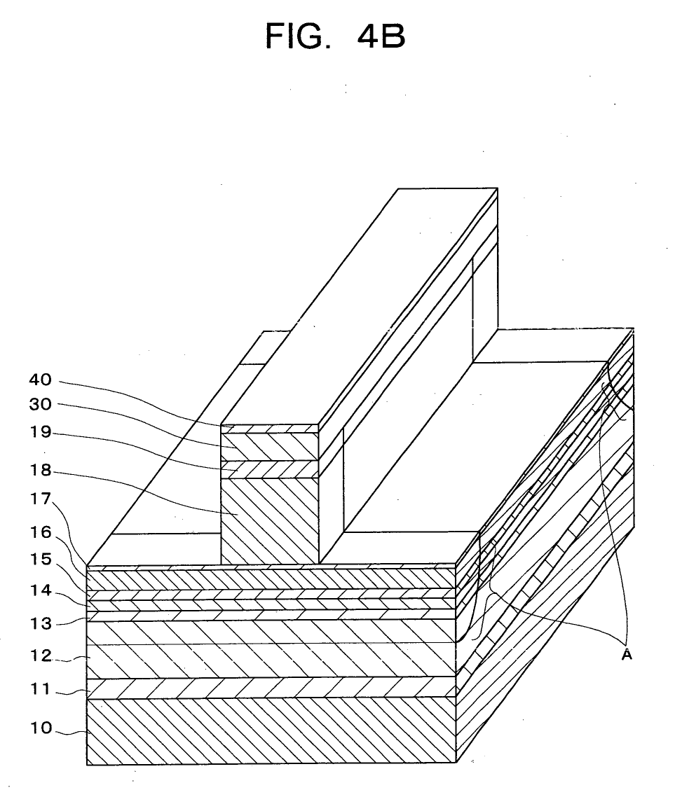

Next, as shown in FIG. 3B, the zinc diffusion source 250 and a SiO₂ mask are removed, so that the entire surface of the p-In_{0.5}Ga_{0.5}P intermediate layer 19 is exposed. Then as shown in FIG. 4A, on the p-In_{0.5}Ga_{0.5}P intermediate layer 19, a p-GaAs contact layer 30 with a carbon dopant is formed by, for example, a MOCVD method. Here, for doping of carbon, carbon tetrabromide can be used as a dopant material. Alternatively, a mol ratio of trimethylgallium to arsine, which are materials at the time of the contact layer 30 growth, can be set to be gallium-richer than in a usual GaAs growth condition, so that carbon in the material is automatically doped.

Incidentally, a thickness of the formed contact layer 30 is, for example, 300 nm. A carrier concentration thereof is preferable to be between 1×10¹⁹cm⁻³ and 5×10¹⁹cm⁻³. The lower limit is set in view of an easy ohmic connection to a p-side electrode 23. The upper limit does not basically exist, but is set here in view of easy manufacturing.

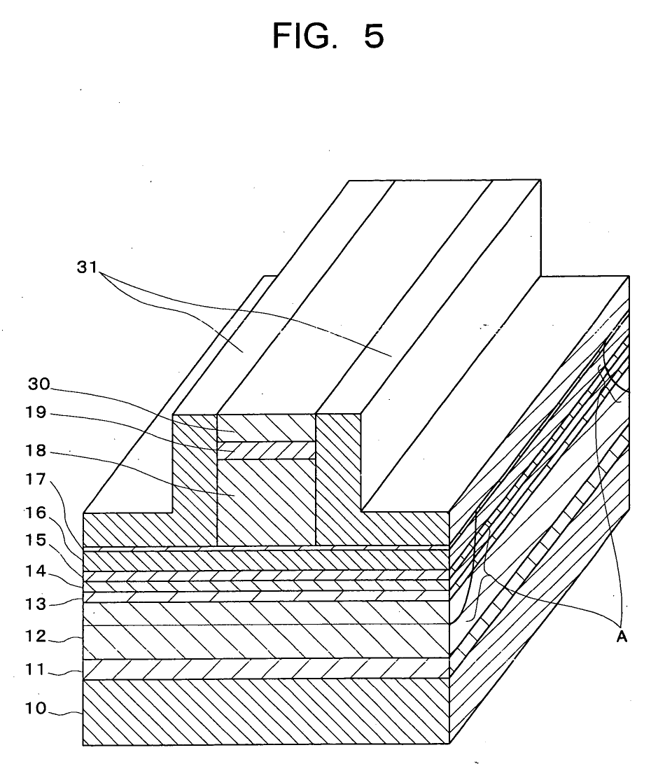

Next, as shown in FIG. 4B, on a surface of the p-GaAs contact layer 30 a stripe mask 40 of SiO₂ is formed, and with the mask thereof, dry etching is first conducted and then wet etching is conducted so that layers from the P-GaAs contact layer 30 to p-In_{0.5}(Ga_{0.3}Al_{0.7})_{0.5}P clad layer 18 are converted into a ridge stripe shape. Here, a width of the ridge stripe is, for example, 2-3 μm. Subsequently, the current stopping layer 31 of SiO₂ is deposited on the entire surface of a state shown in FIG. 4B, and then as shown in FIG. 5, by using for example the photolithography technology, only a ridge stripe portion is made open. A thickness of the current stopping layer 31 is, for example, 0.3-0.4 μm on the etching stop area 17 as well as on side surfaces of the clad layer 18, the intermediate layer 19, and the contact layer 30.

In a subsequent step, which is not shown, the p-side electrode 23 is formed, so as to contact the top surface of the contact layer 30, on the entire surface of the formed layers described above. Additionally, after polishing a rear surface of the substrate 10 to make the height of the semiconductor laser element as a whole to be approximately 100-110 μm, on an entire surface of this rear surface the n-side electrode 22 is formed. The p-side electrode 23 as well as the n-side electrode 22 can be a stacked film containing a predetermined metal thin film, for example, and a combined thickness thereof is, for example, a little less than 1 μm. As a formation method thereof, for example, evaporation can be used.

Thereafter, a wafer is cleavaged into bars along a line which divides a zinc diffused area in two in a right angle direction to the stripe. Then, after an end face protection film is applied on cleavage surfaces, the wafer is cut parallel to the stripe, at a position between the stripe and the neighboring stripe, and divided into chips. According thereto, the semiconductor laser element shown in FIG. 1 is obtained.

In this semiconductor laser element, the dielectric film is used for the current stopping layer 31, and a semiconductor material is not used. Consequently, an optical output efficiency is not deteriorated by increase in a leak current, therefore this semiconductor laser element is suited for a high output power. Moreover, though the current stopping layer 31 of the dielectric is formed after formation of the, p-GaAs contact layer 30 which is doped with carbon in high concentration, with diffusibility of carbon being relatively low a light emission of the semiconductor laser element is relieved from being deteriorated by diffusion of this carbon toward the active layer 14. Additionally, it can be avoided that a lack of the carrier concentration of the p-GaAs contact layer 30 causes non-alloy type ohmic electrode formation at the p-side electrode 23 to be difficult. Also, the contact layer 30 in itself keeps low resistance and characteristics as the contact layer can be kept even through a thermal history at the time of forming the current stopping layer 31. According to the above, it becomes possible to emit a light of a high output power by an operation at a low threshold voltage.

Incidentally, in the above embodiment, as a material of the current stopping layer 31 of the dielectric, other dielectric than silicon oxide can be used. For example, silicon nitride or zirconium oxide is conceivable. Meanwhile, it is also conceivable, if a specification requires, that instead of the current stopping layer 31 of the dielectric, a current stopping layer of a semiconductor material with n-InAlP (lower layer) and n-GaAs (upper layer) being layered, for example, is used. In this case, for example, the n-InAlP layer can be around 0.2-1 μm thick with a dopant concentration of 1×10¹⁸cm⁻³ to 5×10¹⁸cm⁻³, while the n-GaAs layer can be 5-500 nm thick with a comparable dopant concentration. As for the leak current, this is not as advantageous as the current stopping layer of the dielectric, but can be acceptable depending on the specification.

Further, in the above embodiment (including a modification example in the above paragraph), in each case, the above-described window structure (“A” part) is formed before formation of the p-GaAs contact layer 30. Consequently, the above embodiment is-suited for obtaining a semiconductor laser element compliant to a high output power.

Additionally, in the above embodiment, according to the material system thereof an emitted light wavelength is approximately 650 nm. An optical output power thereof can comply with a light emission of 200 mW and above. The above embodiment can be applied to a case of changing the material system so as to change the wavelength (for example, change to 780 nm for a CD). Moreover, as a combination of the dopant for the p-In_{0.5}(Ga_{0.3}Al_{0.7})_{0.5}P clad layer 18 and the dopant for the p-GaAs contact layer 30, besides zinc/carbon which is described in the above embodiment, zinc/magnesium or magnesium/carbon can be conceived. In each combination, a diffusion velocity of the material after “/” is slower, therefore a similar effect can be expected.

Further, as another modification of the above described embodiment of a manufacturing method, a method of growing and forming the layers to the p-GaAs contact layer 30 in the step of FIG. 2A is conceivable. Note, however, that in this case, the zinc diffusion source 250 is formed on the contact layer 30 in the step shown in FIG. 3A. Consequently, since the GaAs contact layer 30 which contains carbon in high concentration becomes a trap source of solid phase diffused zinc, zinc diffusion for the purpose of forming the window structure fails to progress smoothly. If this disadvantage can be allowed, such a method is adoptable. Incidentally, use of other method than zinc solid phase diffusion can be conceived in order for smooth progress. For example, use of ion implantation or use of an element which is hard to be trapped instead of zinc is conceivable.

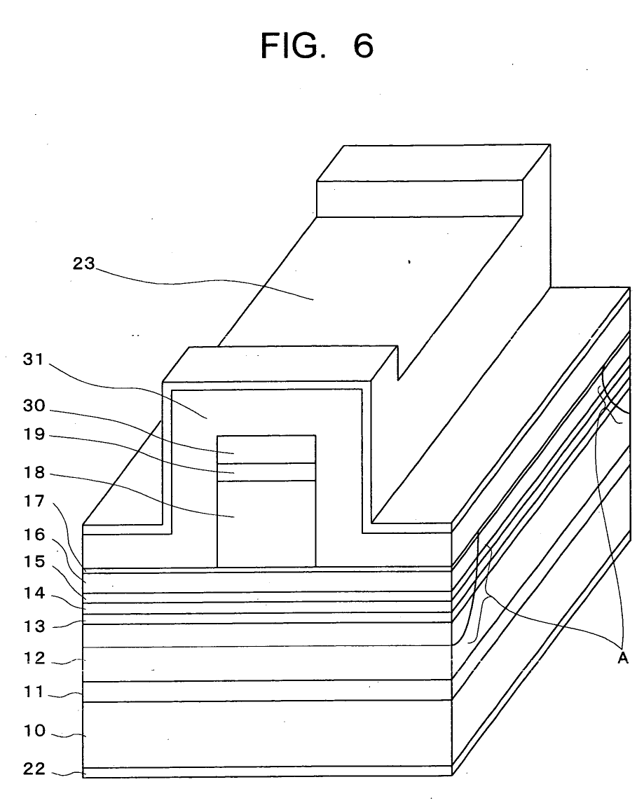

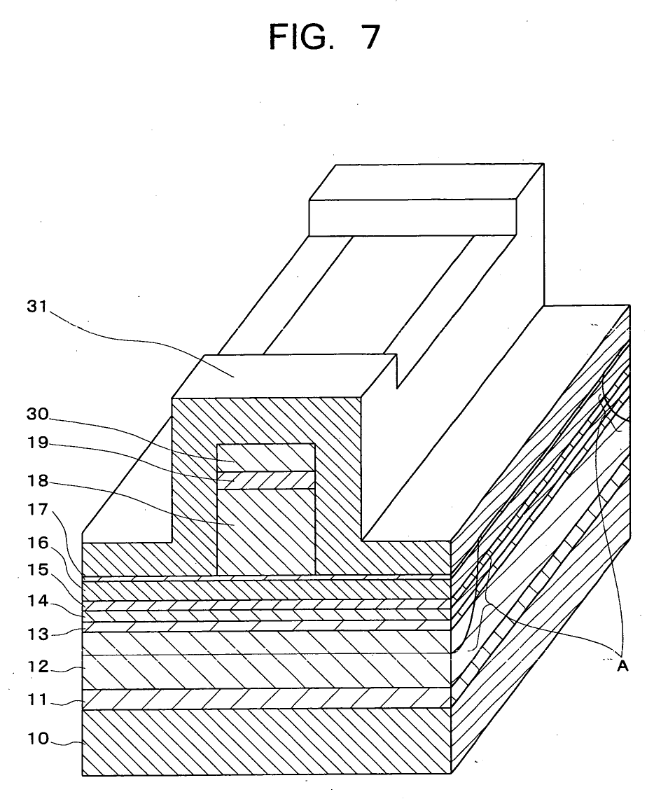

Next, another embodiment of the present invention will be described with reference to FIG. 6 and FIG. 7. FIG. 6 is a perspective view which schematically shows a structure of a semiconductor laser device according to another embodiment of the present invention. FIG. 7 is a perspective view which schematically shows a structure before formation of a p-side electrode 23 and an n-side electrode 22 in the structure shown in FIG. 6. Note that in FIG. 6 and FIG. 7 the same reference numerals and symbols are used to designate the same elements as those already described. Explanation thereof will be restrained whenever possible.

As shown in FIG. 6 and FIG. 7, this embodiment differs from the above-described embodiment in that a current stopping layer 31 is formed so as to cover also top surfaces in neighborhood of end faces of a contact layer 30. According thereto, a current stopping effect is exerted also on the end faces, to suppress a current which does not contribute to a light emission in a case that a window structure is formed, and to suppress a Joule heat thereof. Consequently, this can further contribute to a more highly efficient light emission. Here, a width of the current stopping layer 31 on the top surface of the contact layer 31 is, for example, 20-30 μm, which is larger to a certain degree than that in the zinc diffusion source 250 (see FIG. 3A) for forming the window structure.

Incidentally, in each embodiment described above, though a red semiconductor laser element is taken as an example for explanation, the present invention is applicable to a laser element which emits other colors than red, such as a blue-violet laser element of a GaN base material and an infrared laser element of an In InGaAsP base material or an AlGaAs base material.

The present invention is not limited to the specific forms described here with the illustrations, but it is to be understood that all the changes and modifications without departing from the range of the following claims are to be included therein.

1. A semiconductor laser element, comprising:
a double heterojunction structure having an n-type clad layer, an active layer formed on the n-type clad layer, and a p-type clad layer formed on the active layer;
a second p-type clad layer formed on the double heterojunction structure, containing a first dopant, and having a ridge shape;
a p-type contact layer formed on the second p-type clad layer and containing a second dopant of which a diffusion velocity is slower than that of the first dopant;
a dielectric film covering a side surface of the second p-type clad layer, a side surface of the p-type contact layer, and a surface on which the second p-type clad layer is not formed on the double heterojunction structure; and
a p-side electrode formed on the p-type contact layer.

2. A semiconductor laser element, comprising:
a double heterojunction structure having an n-type clad layer, an active layer formed on the n-type clad layer, and a p-type clad layer formed on the active layer;
a second p-type clad layer formed on the double heterojunction structure, containing a first dopant, and having a ridge shape;
a p-type contact layer formed on the second p-type clad layer and containing a second dopant of which a diffusion velocity is slower than that of the first dopant; and
a p-side electrode formed on the p-type contact layer;
wherein an end face of a cleavage of the double heterojunction structure is an unmarshalled layer structure.

3. The semiconductor laser element as set forth in claim 1, wherein the first dopant/the second dopant is zinc/carbon, zinc/magnesium, or magnesium/carbon.

4. The semiconductor laser element as set forth in claim 1, wherein the active layer is a single quantum well structure or a multiple quantum well structure.

5. The semiconductor laser element as set forth in claim 1, wherein an end face of a cleavage of the double heterojunction structure is an unmarshalled layer structure.

6. The semiconductor laser element as set forth in claim 1, wherein the dielectric film is a film essentially composed of silicon oxide.

7. The semiconductor laser element as set forth in claim 1, wherein the n-type clad layer, the p-type clad layer, and the second p-type clad layer have an InGaAlP composition while the active layer has an InGaP composition.

8. The semiconductor laser element as set forth in claim 1, wherein the p-type contact layer has a GaAs composition while a carrier concentration of the p-type contact layer is 1×10¹⁹cm⁻³ to 5×10¹⁹cm^{31 3}.

9. The semiconductor laser element as set forth in claim 1, wherein a wavelength of an emitted laser light is approximately 650 nm.

10. The semiconductor laser element as set forth in claim 1, wherein the dielectric film covers also a part of a top surface in neighborhood of an end face of the p-type contact layer.

11. The semiconductor laser element as set forth in claim 1, wherein an output power of an emitted laser light is able to be 200 mW and above.

12. The semiconductor laser element as set forth in claim 2, wherein the first dopant/the second dopant is zinc/carbon, zinc/magnesium, or magnesium/carbon.

13. The semiconductor laser element as set forth in claim 2, wherein the active layer is a single quantum well structure or a multiple quantum well structure.

14. The semiconductor laser element as set forth in claim 2, wherein the n-type clad layer, the p-type clad layer, and the second p-type clad layer have an InGaAlP composition while the active layer has an InGaP composition.

15. The semiconductor laser element as set forth in claim 2, wherein the p-type contact layer has a GaAs composition while a carrier concentration of the p-type contact layer is 1×10¹⁹cm⁻³ to 5×10¹⁹cm⁻³.

16. The semiconductor laser element as set forth in claim 2, wherein a wavelength of an emitted laser light is approximately 650 nm.

17. The semiconductor laser element as set forth in claim 2, wherein an output power of an emitted laser light is able to be 200 mW and above.

18. A semiconductor laser element manufacturing method, comprising:
forming a double heterojunction structure which has an n-type clad layer, an active layer positioned on the n-type clad layer, and p-type clad layer positioned on the active layer;
forming a second p-type clad layer on the formed double heterojunction structure;
forming a p-type contact layer which contains carbon as a dopant on the formed second p-type clad layer;
converting the second p-type clad layer and the p-type contact layer into a ridge shape;
depositing a dielectric film on a side surface of the second p-type clad layer and the p-type contact layer converted into the ridge shape as well as on a surface on which the second p-type clad layer is not formed on the double heterojunction structure; and
forming a p-side electrode to contact a top surface of the p-type contact layer.

19. The semiconductor laser element manufacturing method as set forth in claim 18, further comprising unmarshalling a layer structure in a partial area of the double heterojunction structure after forming the second p-type clad layer and before forming the p-type contact layer.
